(19) United States
(12) Patent Application Publication
(10) Pub. No.: US 2006/0222971 A1
(43) Pub. Date: Oct. 5, 2006

(54) Display apparatus substrate and manufacturing method, and a display apparatus thereof

(75) Inventors: Jong-Hyun Seo, Seoul (KR); Hyung-Il Jeon, Incheon Gwangyeock-si (KR)

Correspondence Address: MACPHERSON KWOK CHEN & HEID LLP, 1762 TECHNOLOGY DRIVE, SUITE 226, SAN JOSE, CA, 95110, US

(73) Assignee: Samsung Electronics Co., Ltd.

(21) Appl. No.: 11/446,035

(22) Filed: Jun. 2, 2006

(30) Foreign Application Priority Data
Feb. 6, 2005 (KR) 2005-47292

(51) Int. Cl. G03F 1/00

(52) U.S. Cl. 430/7

(57) ABSTRACT

A substrate includes a hydrophobic body, a hydrophilic body portion and a hydrophilic thin film. The hydrophilic body portion is formed on the hydrophobic body. The hydrophilic thin film is formed on the hydrophilic body portion to form a display element. In a method of manufacturing the substrate, a bare hydrophobic substrate is disposed in a plasma chamber. A hydrophilic body portion is formed on a surface of the bare substrate by exposing bare substrate to plasma generated in the plasma chamber. The hydrophilic image display elements may be formed on a flexible substrate so that the display elements are tightly attached to the flexible substrate.

### CROSS-REFERENCE TO RELATED APPLICATIONS

This application relies for priority upon Korean Patent Application No. 2005-47292 filed on Jun. 2, 2005, the contents of which are herein incorporated by reference in its entirety.

### BACKGROUND OF THE INVENTION

1. Field of the Invention

The present invention relates to a substrate for a display apparatus, a method of manufacturing the substrate, and a display apparatus having the substrate. More particularly, the present invention relates to a substrate capable of preventing a thin layer of a display element for displaying an image from being separated from a flexible substrate, a method of manufacturing the substrate, and a display apparatus having the substrate.

2. Description of the Related Art

A display element converts an electric signal processed by an information-processing device into an image. eExemplary display elements can include, without limitation, a liquid crystal display (LCD), an organic light emitting device (OLED), and a plasma display panel (PDP). In general, these display elements display an image using pixels. Traditionally, pixels are formed on a hard substrate, such as glass. However, a display element having a hard substrate may have disadvantages, and it would be advantageous to form a display element on a flexible substrate. However, current flexible substrates tend to be susceptible to delamination from attached thin films. For example, a thin film formed on a flexible substrate, as can occur with thin film transistors (TFT) may easily separate from the substrate upon which it is formed. Thus, there is a need to provide a flexbile substrate which allows thin films to be formed thereupon but which is not as susceptible to delamination. A method of manufacturing such a substrate and a display apparatus employing such a flexible substrate are desirable.

### SUMMARY OF THE INVENTION

Embodiments herein provide a substrate capable of preventing a thin layer for displaying an image in a display apparatus from being separated from a flexible substrate. Also provided are a method of manufacturing the above-mentioned substrate, and a display apparatus having the above-mentioned substrate.

Exemplary substrate embodiments herein include a hydrophobic body, a hydrophilic body portion and a hydrophilic thin film. The hydrophilic body portion is formed on the hydrophobic body and the hydrophilic thin film is formed on the hydrophilic body portion. The hydrophilic thin film forms a display element. Exemplary method embodiments dispose a a bare hydrophobic substrate in a plasma chamber. A hydrophilic body portion can be formed on a surface of the bare hydrophobic substrate by exposing the bare hydrophobic substrate to plasma generated in the plasma chamber. Exemplary display apparatus herein can include a first substrate, a second substrate, and a display element. The first substrate can have a first hydrophobic body, and a first hydrophilic body portion formed on the first hydrophobic body. The second substrate can have a second hydrophobic body and a second hydrophilic body portion that is formed on the second hydrophobic body. The second hydrophilic body portion generally corresponds to the first hydrophilic body portion. A display element for displaying an image is disposed between the first and second substrates, with the display element including a hydrophilic thin film. Accordingly, display elements for displaying an image may be formed on a flexible substrate so that the display elements are tightly attached to the flexible substrate.

### BRIEF DESCRIPTION OF THE DRAWINGS

The above and other features and advantages of the present invention will become more apparent by describing in detailed example embodiments thereof with reference to the accompanying drawings, in which:

FIG. 1 is a cross-sectional view illustrating a substrate for a display apparatus according to an example embodiment of the present invention;

FIG. 2 is a cross-sectional view illustrating a substrate for a display apparatus according to another example embodiment of the present invention;

FIG. 3 is a cross-sectional view illustrating a substrate for a display apparatus according to still another example embodiment of the present invention;

FIG. 4 is an enlarged view illustrating a portion ‘A’ in FIG. 3;

FIG. 5 is a cross-sectional view illustrating a substrate for a display apparatus according to still another example embodiment of the present invention;

FIG. 6 is a schematic view illustrating characteristics of hydrophobic body portion of a substrate for a display apparatus of the present invention;

FIG. 7 is a schematic view illustrating characteristics of hydrophilic body portion of a substrate for a display apparatus of the present invention;

FIG. 8 is a cross-sectional view illustrating a thin film transistor formed on a substrate for a display apparatus of the present invention;

FIG. 9 is a schematic plan view of the thin film transistor in FIG. 8;

FIG. 10 is a flow chart showing a method of manufacturing a substrate for a display apparatus according to the present invention;

FIGS. 11A to 16B are cross-sectional views illustrating characteristics of a substrate for a display apparatus according to the present invention;

FIG. 17 is a histogram illustrating a relationship between a contact angle and the substrates in FIGS. 11A to 16B;

FIG. 18 is a cross-sectional view illustrating a display apparatus according to an example embodiment of the present invention; and

FIG. 19 is a cross-sectional view illustrating a display apparatus according to another example embodiment of the present invention.

### DESCRIPTION OF EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to,”or “coupled to” another element or layer, it can be directly on, connected or coupled to the other element or layer or intervening elements or layers may be present. In contrast, when an element is referred to as being “directly on,” “directly connected to,” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only, and is not intended to be limiting of the invention. As used herein, the singular forms “a,” “an” and “the” are intended to include the plural forms as well, unless the context clearly indicates otherwise.

Embodiments of the invention are described herein with reference to cross-section illustrations that may be schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than an abrupt change from an implanted region to a non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Substrate for a Display Apparatus

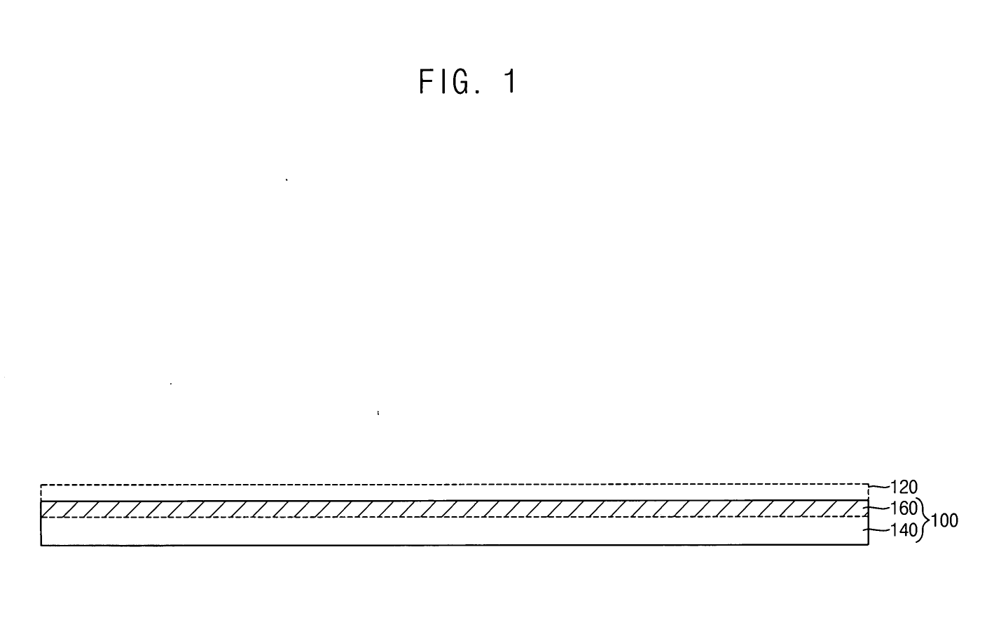

Referring to FIG. 1, hydrophilic thin film 120 can be formed on flexible substrate 100 as a display element for displaying an image. Substrate 100 can include hydrophobic body 140 and hydrophilic body portion 160. Hydrophobic body 140 can be formed from synthetic resins, including without limitation, polycarbonate, polyethylenenaphthelate, polyethyleneterephehalate polyimide, polyethersulphone, and polyacrylate. Thin film 120 can be, for example, a silicon nitride (SiNx) film. Typically, a hydrophilic thin films formed directly on a flexible hydrophobic substrate tends to easily delaminate, or separate from the substrate. Embodiments of the invention herein can substantially ameliorate delamination of a hydrophilic thin film, such as film 120, from an underlying hydrophobic substrate, such as body 140, by interposing therebetween a hydrophilic body portion, such as hydrophilic body portion 160. Accordingly, in embodiments of the present invention, it can be advantageous to dispose hydrophilic body portion 160 between hydrophilic thin film 120 and hydrophobic body 140. In general, it is desirable to form the hydrophilic thin film 120 on hydrophilic body portion 160 such that thin film 120 can be tightly attached to hydrophilic body portion 160. It can be advantageous to integrally form hydrophilic body portion 160 with the body 140, thereby providing substrate 100. Alternative embodiments of substrate 100 may provide that hydrophilic body portion 160 be formed separately from hydrophobic body 140.

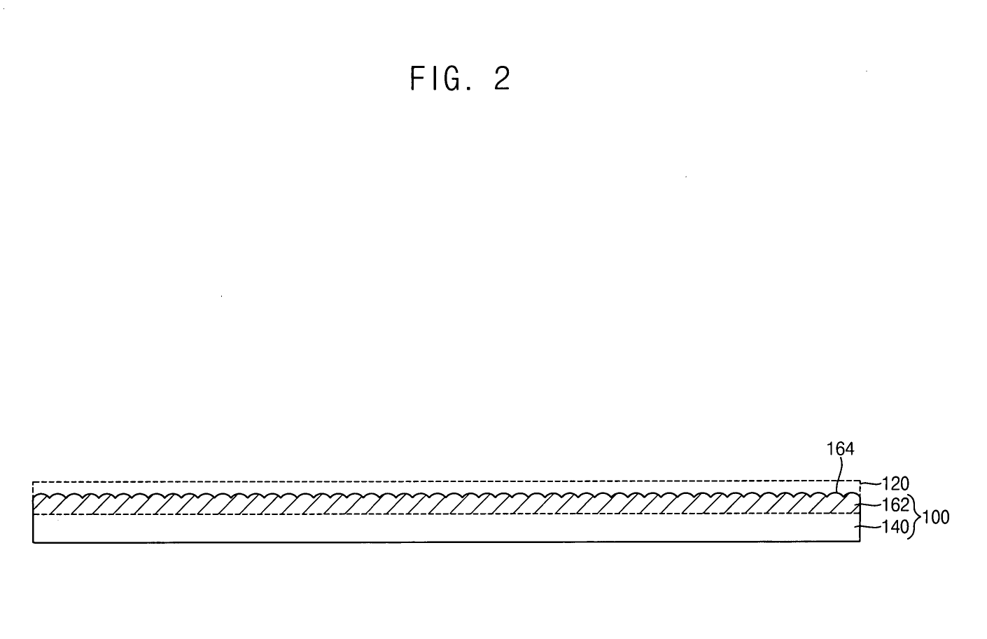

Referring to FIG. 2, hydrophilic thin film 120 can be formed on flexible substrate 100 as a display element for displaying an image. Substrate 100 can include hydrophobic body 140 and hydrophilic body portion 162. Hydrophobic body 140 can be formed from synthetic resins, including without limitation, polycarbonate, polyethylenenaphthelate, polyethyleneterephehalate polyimide, polyethersulphone, and polyacrylate. Thin film 120 can be, for example, a silicon nitride (SiNx) film. Typically, a hydrophilic thin films formed directly on a flexible hydrophobic substrate tends to easily delaminate, or separate from the substrate. Embodiments of the invention herein can substantially ameliorate delamination of a hydrophilic thin film, such as film 120, from an underlying hydrophobic substrate, such as body 140, by interposing therebetween a hydrophilic body portion, such as hydrophilic body portion 162. Accordingly, in embodiments of the present invention, it can be advantageous to dispose hydrophilic body portion 162 between hydrophilic thin film 120 and hydrophobic body 140. In general, it is desirable to form the hydrophilic thin film 120 on hydrophilic body portion 162 such that thin film 120 can be tightly attached to hydrophilic body portion 162. It can be advantageous to integrally form hydrophilic body portion 160 with hydrophobic body 140, thereby providing substrate 100. Alternative embodiments of substrate 100 may provide that hydrophilic body portion 162 be formed separately from hydrophobic body 140.

In order to enhance adhesive force between thin film 120 and hydrophilic body portion 162, embossing patterns 164 may be formed on the hydrophilic body portion 162. Embossing patterns 164 generally increase a contact area between thin film 120 and hydrophilic body portion 162, thereby enhancing an adhesive force between thin film 120 and hydrophilic body portion 162.

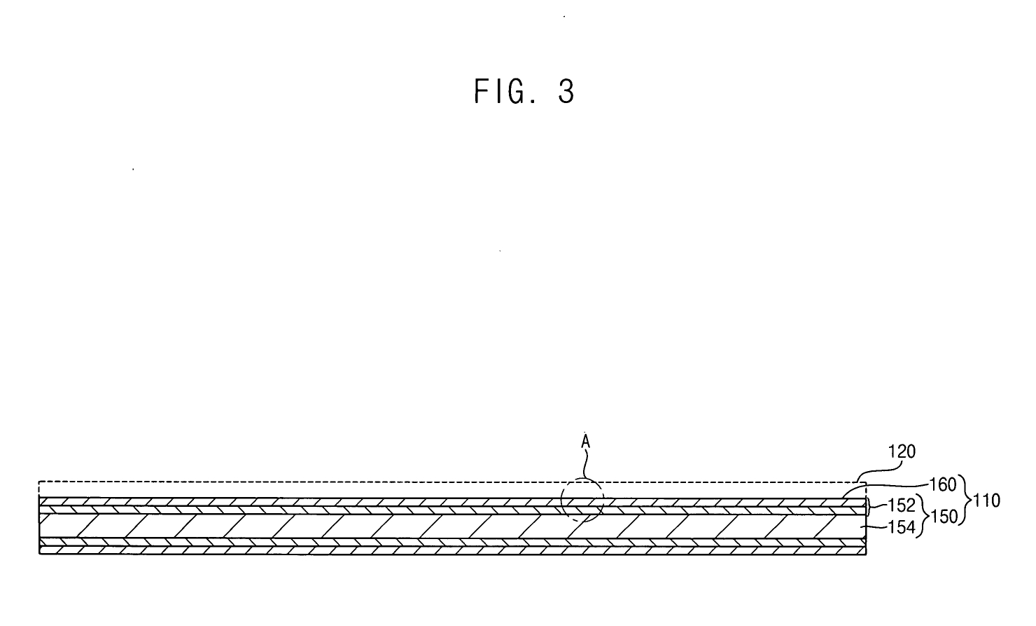

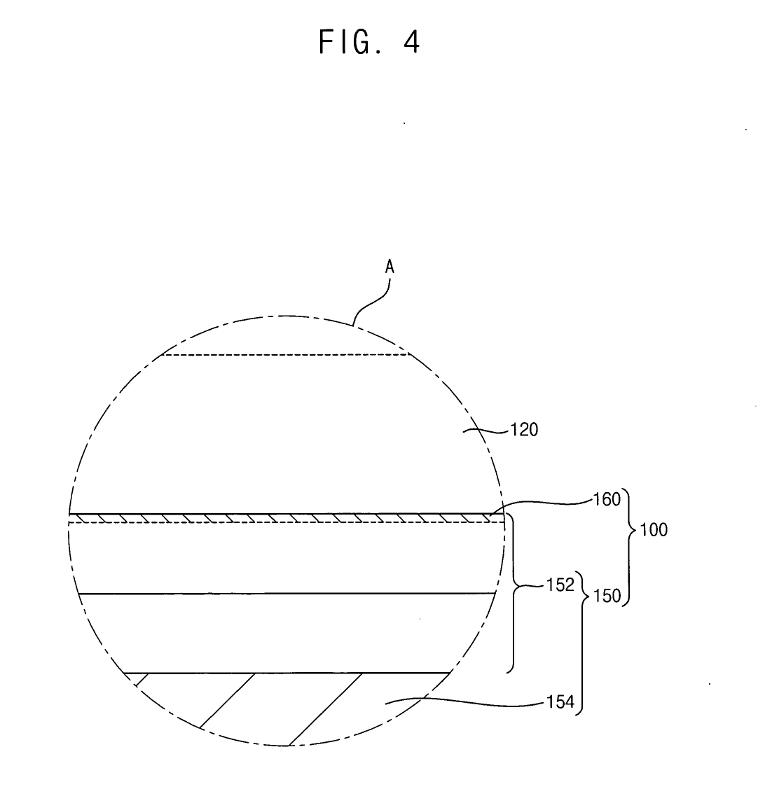

Referring to FIGS. 3 and 4, hydrophilic thin film 120 can be formed on flexible substrate 100 as a display element for displaying an image. Substrate 100 can include hydrophobic body 150 and hydrophilic body portion 160. Hydrophobic body 150 can be formed from synthetic resins, including without limitation, polycarbonate, polyethylenenaphthelate, polyethyleneterephehalate polyimide, polyethersulphone, and polyacrylate. According to the present embodiment, substrate body 150 may have at least two hydrophobic films, including main body 152, having a first thickness, and sub-body 154, having a second thickness that is thinner than the first thickness. Sub-body 154 can be formed on upper and lower faces of main body 152 sub-body. Desirably, main body 152 and sub-body 154 can be substantially hydrophobic and be formed, for example, from synthetic resins, including without limitation, polycarbonate, polyethylenenaphthelate, polyethyleneterephehalate polyimide, polyethersulphone, and polyacrylate. Main body 152 can providesubstrate body 150 with enough strength for maintaining a shape of a substrate 100. Sub-body 154 tends to prevent a deleterious invasion of moisture, or of oxygen gas to main body 152.

Typically, hydrophilic thin films formed directly on a flexible hydrophobic substrate tends to easily delaminate, or separate from the underlying substrate. Embodiments of the invention herein can substantially ameliorate delamination of a hydrophilic thin film, such as film 120, from an underlying hydrophobic substrate, such as sub-body 154, by interposing therebetween a hydrophilic body portion, such as hydrophilic body portion 162. Accordingly, in embodiments of the present invention, it can be advantageous to dispose hydrophilic body portion 162 between hydrophilic thin film 120 and hydrophobic sub-body 154. In general, it is desirable to form the hydrophilic thin film 120 on hydrophilic body portion 162 such that thin film 120 can be tightly attached to hydrophilic body portion 162. It can be advantageous to integrally form hydrophilic body portion 160 with hydrophobic body 150, thereby providing substrate 100. Alternative embodiments of substrate 100 may provide that hydrophilic body portion 162 be formed separately from hydrophobic body 150.

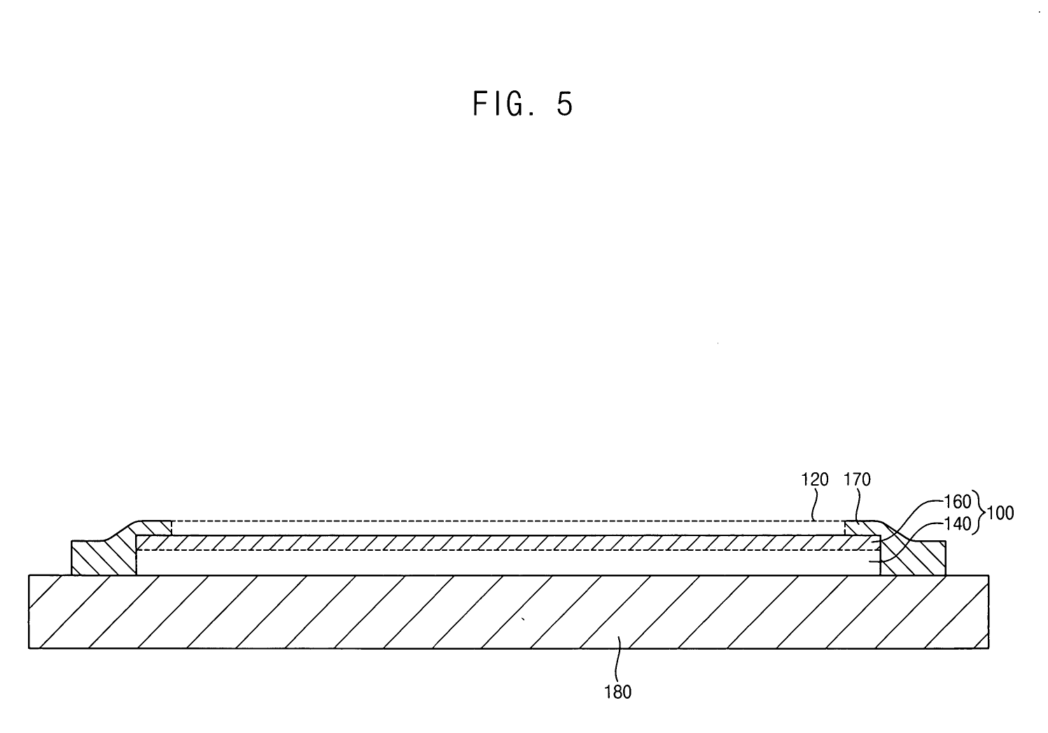

Referring to FIG. 5, hydrophilic thin film 120 can be formed on flexible substrate 100 as a display element for displaying an image. Substrate 100 can include hydrophobic body 140, hydrophilic body portion 162, sealing member 170, and sub-body 180. Hydrophobic body 140 can be formed from synthetic resins, including without limitation, polycarbonate, polyethylenenaphthelate, polyethyleneterephehalate polyimide, polyethersulphone, and polyacrylate. Thin film 120 can be, for example, a hydrophilic silicon nitride (SiNx) film. Typically, a hydrophilic thin films formed directly on a flexible hydrophobic substrate tends to easily delaminate, or separate from the substrate. Embodiments of the invention herein can substantially ameliorate delamination of a hydrophilic thin film, such as film 120, from an underlying hydrophobic substrate, such as body 140, by interposing therebetween a hydrophilic body portion, such as hydrophilic body portion 160. Accordingly, in embodiments of the present invention, it can be advantageous to dispose hydrophilic body portion 160 between hydrophilic thin film 120 and hydrophobic body 140. In general, it is desirable to form the hydrophilic thin film 120 on hydrophilic body portion 160 such that thin film 120 can be tightly attached to hydrophilic body portion 160. It can be advantageous to integrally form hydrophilic body portion 160 with hydrophobic body 140, thereby providing substrate 100. Alternative embodiments of substrate 100 may provide that hydrophilic body portion 160 be formed separately from hydrophobic body 140.

Sub-body 180 supports the substrate 100, and can prevent substrate 100 from being bent, being warped, or from sagging. In order to support substrate 100, it can be advantageous that sub-body 180 have a higher degree of hardness than that of substrate 100. An exemplary substrate for use as sub-body 180 can be a transparent glass substrate. Alternatively, an opaque substrate of suitable hardness also may be employed as sub-body 180.

Operable thin film patterns can be formed on an upper face of substrate 100 disposed on sub-body 180. The thin film patterns may be formed, for example, through thin film creation processes including without limitation, a thin film deposition, a thin film etching, and a thin film cleaning. However, substances used during the thin film creation process, such as chemicals, water, etc., may penetrate the interface between sub-body 180 and substrate 100, causing sub-body 180 to separate, or delaminate, from substrate 100. To substantially prevent such delamination, sealing member 170 can be disposed along the edges of the substrate 100 to seal the interfacial boundary between sub-body 180 and substrate 100. Embodiments of the present invention also can prevent delamination or separation of substrate 100 from sub-body 180, when display elements are formed on the substrate 100.

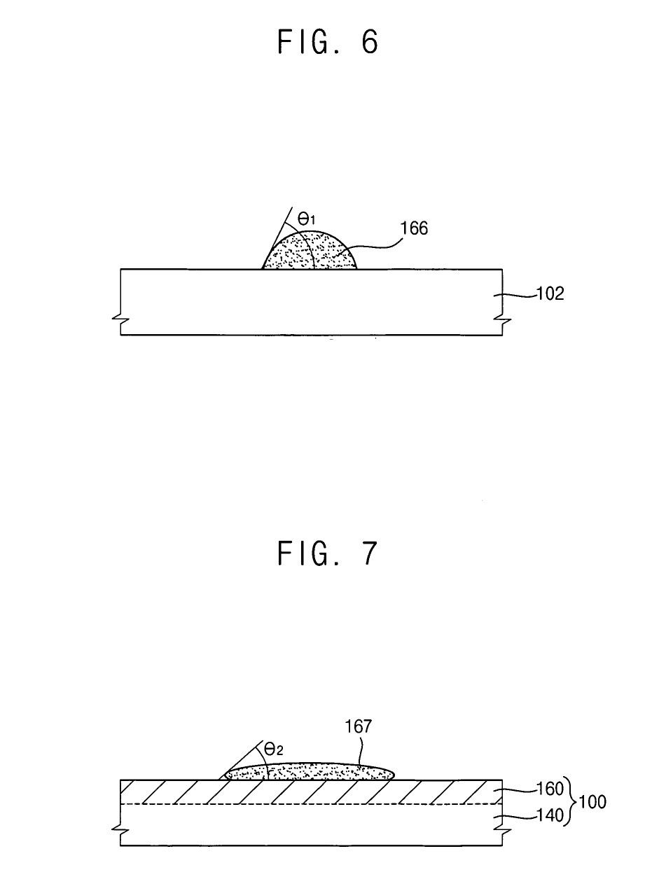

Turning to FIG. 6, water droplet 166, when dropped onto substrate 102, does not spread because substrate 102 is substantially hydrophobic, and a contact angle θ₁ of water droplet 166 with respect to a surface of substrate 102 can be in a range of between about 50 degrees to about 85 degrees of contact angle. In contrast, in FIG. 7, when water droplet 167 is dropped onto body portion 160, which is substantially hydrophilic, water droplet 167 can spread relatively widely over body portion 160, such that a contact angle θ₂ of water droplet 167 with respect to a surface of hydrophilic body portion 160 is in a range of between about 2 degrees to about 50 degrees of contact angle. In selected embodiments of the present invention, substrate 100 can be formed to be hydrophilic, such that a contact angle of a water droplet disposed on the surface of the substrate 100 is in a range of between about 2 degrees to about 50 degrees of contact angle. Desirably, hydrophilic substrate 100 includes hydrophobic body 140; and hydrophilic body portion 160 can be disposed on an upper face of body 140.

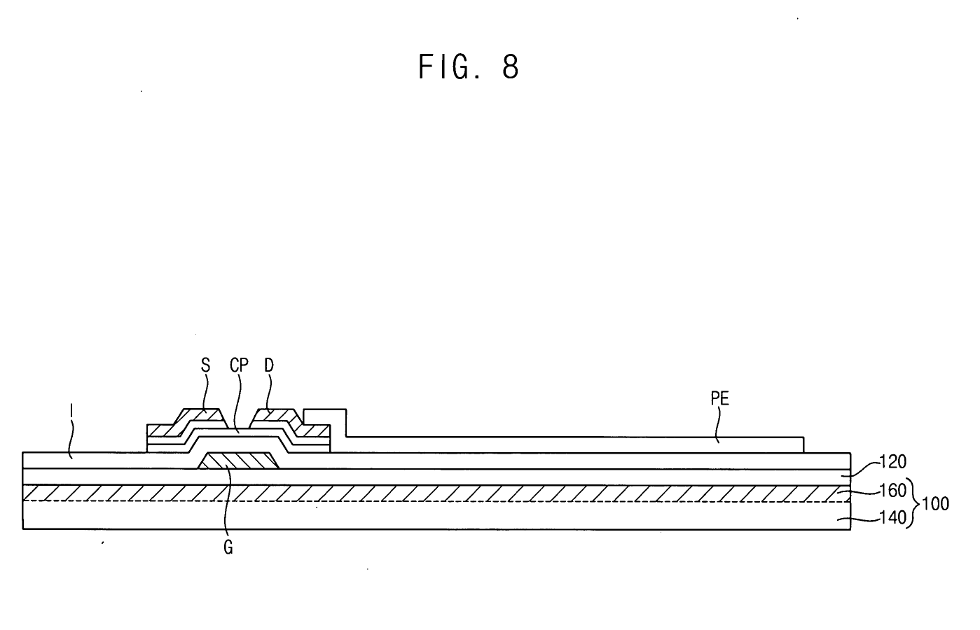

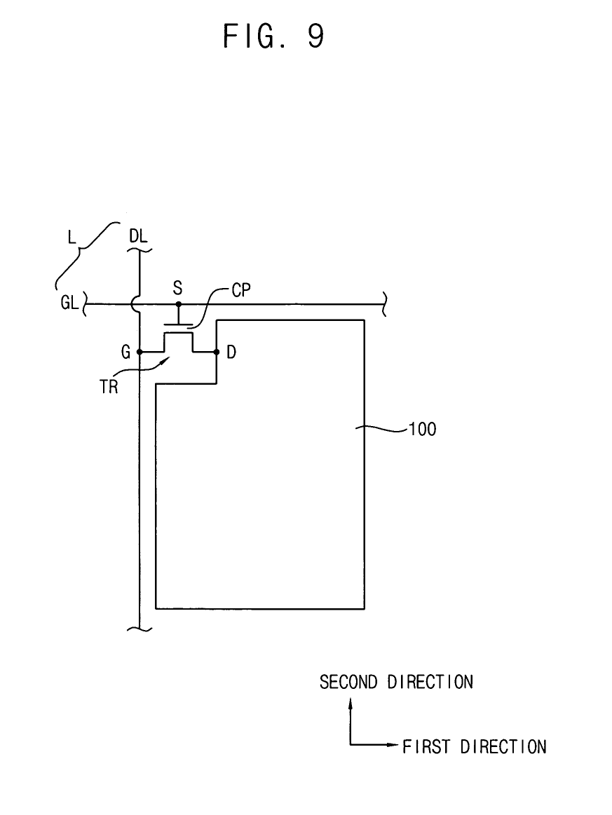

Turning to FIGS. 8 and 9, blocking thin film 120 can be formed on substrate 100 having hydrophobic body 140 formed thereon, with hydrophilic body portion 160 being formed on hydrophobic body 140. Signal line L, thin film transistor TR, and pixel electrode PE may be formed on the blocking thin film 120. Exemplary signal lines include gate line GL and data line DL.

Gate lines, such as gate line GL, can be formed on blocking thin film 120, such that gate lines GL are substantially parallel with each other, and extended along a first direction. A gate electrode G of a thin film transistor TR can protrude from each of the gate lines, as exemplified by gate line GL. Typically, 1,024 gate electrodes G and 768 gate lines are present in a display apparatus having a resolution of 1,024×768 pixels, with each gate line GL transferring a respective gate signal producing the effect of turning thin film transistor TR on or off. Also, gate electrodes, such as gate electrode G can protrude from each of gate lines GL.

Data lines DL can be disposed on insulation layer IL which substantially covers gate lines GL. In an exemplary display apparatus having a resolution of 1024×768 pixels, there are formed 1024×3 data lines DL. In general, data lines DL are substantially parallel with each other, extending along a second direction that is substantially perpendicular to the first direction.

Data lines DL can transfer a data signal provided from an external device. Source electrode S can protrude from each data line DL, with 764 source electrodes S protruding from a respective data line DL, and generally oriented along the second direction.

Exemplary thin film transistor TR can include gate line GL, gate electrode G protruding from the gate line GL, channel pattern CP, data line DL, source electrode S protruding from the data lines DL, and drain electrode D coupled to substrate 100. Channel pattern CP can include an amorphous silicon pattern formed on insulation layer IL facing gate electrode G, and a pair of amorphous silicon patterns formed on the amorphous silicon pattern, with the pair of silicon patterns having dopants injected thereinto. Source electrode S can be disposed on one of the doped amorphous silicon patterns, with drain electrode D being disposed on a remaining doped amorphous silicon patterns. Typically, an optically transparent and electrically conductive material, including without limitation, indium tin oxide (ITO) and indium zinc oxide (IZO), can be formed and patterned to produce pixel electrode PE, with pixel electrode PE being electrically connected to drain electrode D of thin film transistor TR.

Method of Manufacturing a Substrate for a Display Apparatus

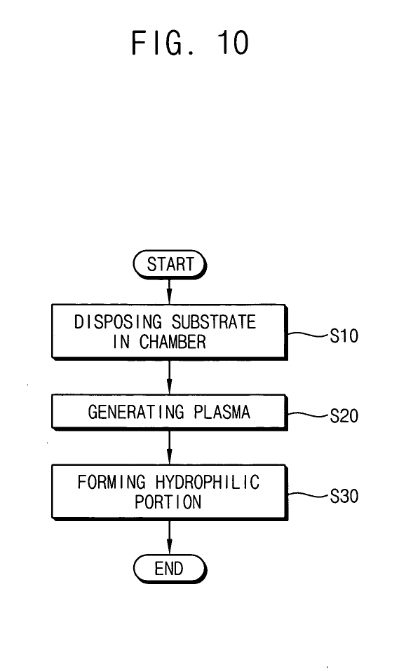

Turning to FIG. 10, a method of manufacturing a substrate for a display apparatus can begin by forming a bare substrate, for example, of hydrophobic synthetic resins, including without limitation, polycarbonate, polyimide, polyethersulphone, polyacrylate, polyethylenenaphthelate, and polyethyleneterephehalate. A hydrophilic thin film formed directly on a hydrophobic bare substrate may be easily detached from the bare substrate. Thus, it can be desirable to change a characteristic of the bare substrate, for example, by disposing substrate 100 in a plasma chamber (step S10), and by exposing substrate 100 to a plasma generated in the plasma chamber (Step S20) using a suitable source gas.

Examples of a suitable source gas for generating the plasma can include without limitation oxygen (O₂), argon (Ar), tetrafluoromethane (CF₄), trifluoromethane (CHF₃), hydrogen chloride (HCl), and a mixture thereof. Selected exemplary embodiments of the present invention can provide oxygen gas (O₂) as the plasma source gas in the plasma chamber. It may be advantageous to adjust an exposure time for exposing the bare substrate to the plasma, according to intensity of the plasma. In general, the bare hydrophobic substrate can be exposed to the plasma for between about 1 second to about 300 seconds, with the time for exposing the bare substrate to the plasma decreasing as the intensity of the plasma increases. As the bare substrate disposed in the chamber reacts with the plasma generated in the plasma chamber, a hydrophilic body portion can be formed on a surface of the bare hydrophobic substrate that is exposed to the plasma, thereby rendering the treated substrate to be suitable as a substrate from which a display apparatus can be manufactured. Additionally, as surface characteristics of the bare substrate are being changed by exposure to plasma, the surface of the bare substrate may be dry-etched by the plasma, and embossing patterns are formed on a surface of the exposed bare substrate. Alternatively, a hydrophilic thin film may be formed on the hydrophilic portion of the hydrophobic bare substrate (step S30), such that when the hydrophilic thin film is formed an adhesive force between the thin film and the bare substrate is enhanced. An exemplary hydrophilic thin film can include without limitation a silicon nitride film.

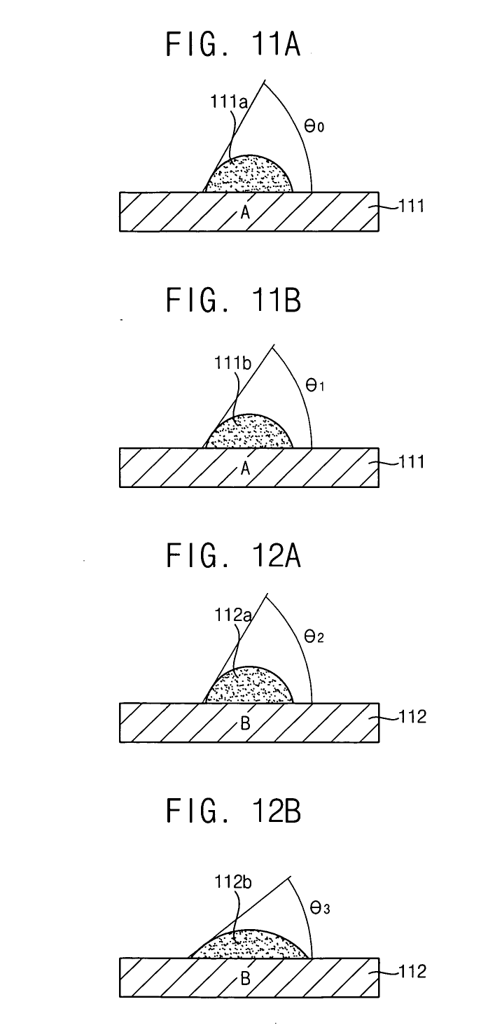

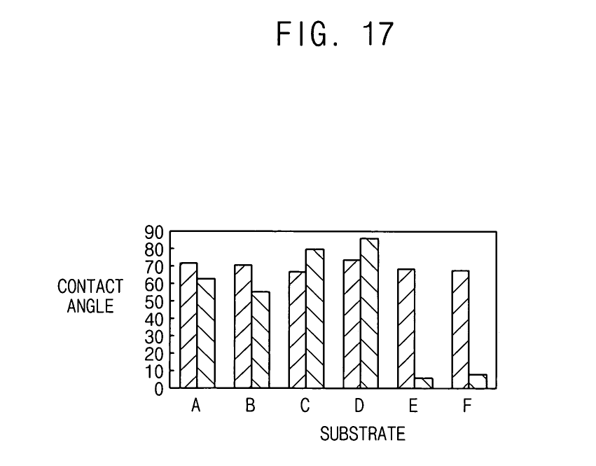

In general, FIGS. 11A to 16B illustrate surface characteristics of a substrate for a display apparatus having a hydrophilic portion. Table 1 information can be representative of the respective substrates, organic cleaning times, hard bake condition, and plasma treatment condition set forth in these Figures. The histogram in FIG. 17 is generally illustrative of the aforementioned surface characteristics as represented by a contact angles between a surface of a substrate sample and a drop of water disposed thereon, with FIGS. 11A, 12A, 13A, 14A, 15A and 16A representing untreated substrate sample surface characteristic, and FIGS. 11B, 12B, 13B, 14B, 15B, and 16B representing a post-treatment substrate sample surface characteristic.

TABLE 1

| | | Hard Bake | Plasma Treatment |
|---|---|---|---|
| | Organic | Condition | Condition |
| Substrate | Cleaning | (approx. temp. and | (approx. power |
| Sample | (approx. time) | approx. time) | and approx. time) |
| A | 240 seconds | — | — |
| B | 480 seconds | — | — |
| C | 240 seconds | 150° C., 30 minutes | — |
| D | 240 seconds | 120° C., 60 minutes | — |
| E | 240 seconds | — | 1,200 W, 30 seconds |
| F | 240 seconds | — | 1,200 W, 50 seconds |

In Table 1, oxygen gas is used as a source gas for plasma. Substrate samples ‘A’ and ‘B’ in Table 1 undergo only an organic cleaning process. Substrate samples ‘C’ and ‘D’ in Table 1 undergo an organic cleaning process and a hard bake process, without a plasma treatment. Substrate samples ‘E’ and ‘F’ in Table 1 undergo an organic cleaning process and a plasma treatment, without a hard bake treatment. Also, sample substrate ‘E’ can be exposed to the plasma for about 30 seconds at 1,200 W of electric power; sample substrate ‘F’ can be exposed to the plasma for about 50 seconds at about 1,200 W of electric power.

To judge whether the substrates are hydrophilic or hydrophobic, water droplets are dropped onto the sample substrates ‘A’, ‘B’, ‘C’, ‘D’, ‘E’ and ‘F’, after which the contact angles of the water droplets with respect to a substrate surface is measured.

For example, in FIG. 11A, a surface property of substrate ‘A’ 111 may be evaluated by dropping water droplet 111a onto the surface of substrate ‘A’ 111 that undergoes no surface treatment prior to organic cleaning, and then by measuring a contact angle θ₀ between the substrate ‘A’ 111 and the water droplet 111a. In FIG. 11B, it is desirable to enhance a surface property of substrate ‘A’ 111 by subjecting a surface of substrate ‘A’ 111 to an organic cleaning process for about 240 seconds. Then, a contact angle θ₁ between substrate ‘A’ 111 and water droplet 111b dropped thereupon is measured, with contact angle θ₁ being generally indicative of the enhanced surface property.

Similarly, in FIG. 12A, a surface property of substrate ‘B’ 112 may be judged by measuring a contact angle θ₂ between substrate ‘B’ 112 and water droplet 112a, dropped thereupon, in which substrate ‘B’ 112 undergoes no surface treatment., Also, FIG. 12B illustrates that a contact angle θ₃ between substrate ‘B’ 112 and water droplet 112b dropped thereupon, is measured after substrate ‘B’ 112 undergoes an organic cleaning process for 480 seconds, with contact angle θ₃ being generally indicative of enhanced surface properties of substrate ‘B’ 112.

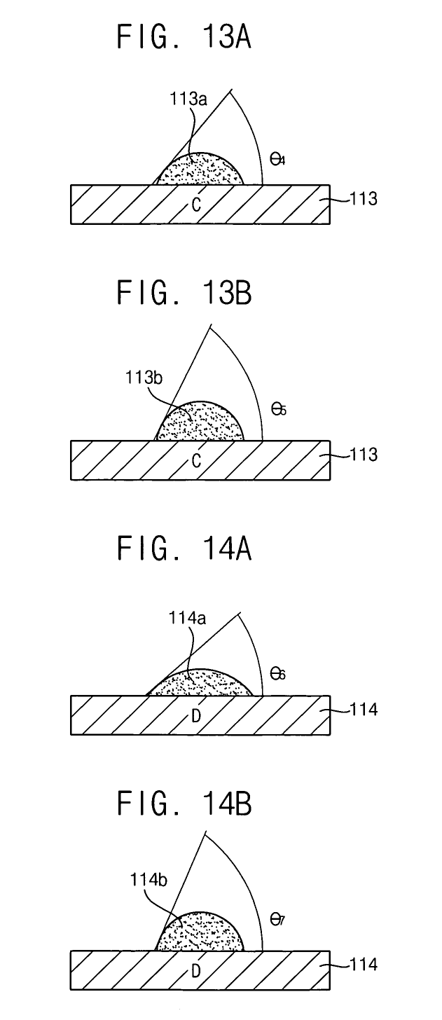

Similarly, in FIG. 13A, a surface property of a substrate ‘C’ 113 may be evaluated by dropping water droplet 113a onto the surface of substrate ‘C’ 113 that undergoes no surface treatment prior to organic cleaning, and then by measuring a contact angle θ₄ between the substrate ‘C’ 113 and the water droplet 113a. In FIG. 13B, it is desirable to enhance a surface property of substrate ‘C’ 113 by subjecting a surface of substrate ‘C’ 113 to a hard baking process at a temperature of about 150° C. for about 30 minutes. Then, a contact angle θ₅ between substrate ‘C’ 113 and water droplet 113b dropped thereupon, is measured, with a contact angle θ₅ being indicative of the enhanced surface property.

Similarly, in FIG. 14A, a surface property of a substrate ‘D’ 114 may be evaluated by dropping water droplet 114a onto the surface of substrate ‘D’ 114 that undergoes no surface treatment prior to organic cleaning, and then by measuring a contact angle θ₆ between the substrate ‘D’ 114 and the water droplet 114a. In FIG. 14B, it is desirable to enhance a surface property of substrate ‘D’ 114 by subjecting a surface of substrate ‘D’ 114 to a hard baking process at a temperature of about 120° C. for about 60 minutes. Then, a contact angle θ₇ between substrate ‘D’ 114 and water droplet 114b dropped thereupon, is measured, with a contact angle θ₇ being indicative of the enhanced surface property.

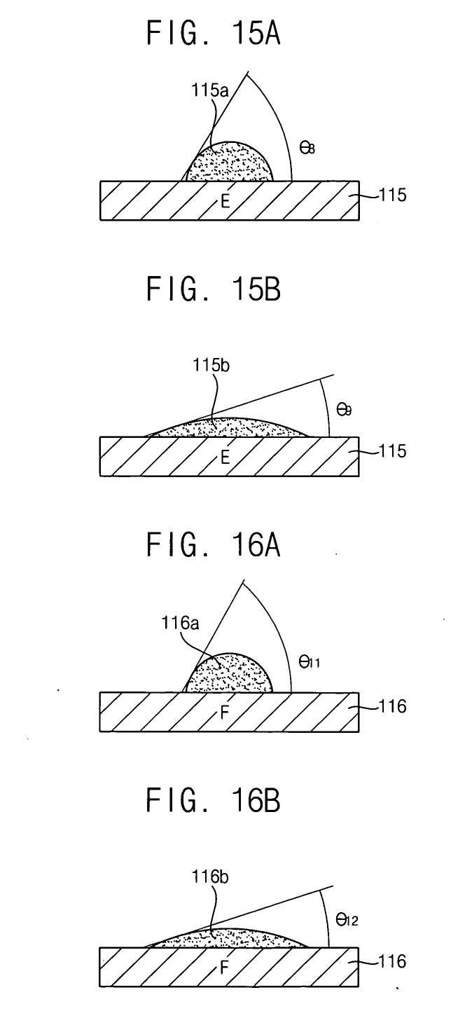

Similarly, in FIG. 15A, a surface property of a substrate ‘E’ 115 may be evaluated by dropping water droplet 115a onto the surface of substrate ‘E’ 115 that undergoes no surface treatment prior to organic cleaning, and then by measuring a contact angle θ₈ between the substrate ‘E’ 115 and the water droplet 115a. In FIG. 15B, it is desirable to enhance a surface property of substrate ‘E’ 115 by subjecting a surface of substrate ‘E’ 115 to a plasma treatment of oxygen plasma generated by 1,200 W electric power for 30 seconds. Then, a contact angle θ₉ between substrate ‘E’ 115 and water droplet 115b dropped thereupon, is measured, with a contact angle θ₉ being indicative of the enhanced surface property.

Similarly, in FIG. 16A, a surface property of a substrate ‘F’ 116 may be evaluated by dropping water droplet 116a onto the surface of substrate ‘F’ 116 that undergoes no surface treatment prior to organic cleaning, and then by measuring a contact angle θ₁₀ between the substrate ‘F’ 116 and the water droplet 116a. In FIG. 16B, it is desirable to enhance a surface property of substrate ‘E’ 116 by subjecting a surface of substrate ‘F’ 116 to a plasma treatment of oxygen plasma generated by 1,200 W electric power for 50 seconds. Then, a contact angle θ₁₁ between substrate ‘F’ 116 and water droplet 116b dropped thereupon, is measured, with a contact angle θ₁₁ being indicative of the enhanced surface property.

FIG. 17 is a histogram illustrating a relationship between a contact angle and the substrates in FIGS. 11A to 16B. FIG. 17 illustrates that, relative to a surface characteristic-altering property induced by a selected surface treatment to substrate ‘A’ 111 as illustrated with respect to FIGS. 11A and 11B, an organic cleaning process with a duration of about 240 seconds may not effect a sufficient change in substrate hydrophobicity, as evidenced by the difference between contact angle θ₀ formed on the surface of substrate A 111 prior to the organic cleaning process (i.e., with water droplet 111a, θ₀ can be about 70°) and contact angle θ₁ formed on the surface of substrate A 111 subsequent to the organic cleaning process (i.e., with water droplet 111b, θ₁ can be about 60°. Thus, a thin hydrophilic film, such as a silicon nitride thin film, may detach relatively easily from a hydrophobic substrate, such as substrate A 111 subject to an organic cleaning process having a duration of about 240 seconds.

FIG. 17 also illustrates that, relative to a surface characteristic-altering property induced by a selected surface treatment to substrate ‘B’ 112 as illustrated with respect to FIGS. 12A and 12B, an organic cleaning process with a duration of about 480 seconds may not effect a sufficient change in substrate hydrophobicity, as evidenced by the difference between contact angle θ₂ formed on the surface of substrate B 112 prior to the organic cleaning process (i.e., with water droplet 112a, θ₂ can be about 70°); and contact angle θ₃ formed on the surface of substrate B 112 subsequent to the organic cleaning process (i.e., with water droplet 112b, θ₃ can be about 55°). Thus, a thin hydrophilic film, such as a silicon nitride thin film, may detach relatively easily from a hydrophobic substrate, such as substrate B 112 subject to an organic cleaning process having a duration of about 480 seconds.

FIG. 17 also illustrates that, relative to a surface characteristic-altering property induced by a selected surface treatment to substrate ‘C’ 113 as illustrated with respect to FIGS. 13A and 13B, a hard baking process at a temperature of about 150° C. for about 30 minutes may not effect a sufficient change in substrate hydrophobicity, as evidenced by the difference between contact angle θ₄ formed on the surface of substrate C 113 prior to the hard baking process (i.e., with water droplet 113a, θ₄ can be about 70°); and contact angle θ₅ formed on the surface of substrate C 113 subsequent to the hard bake process (i.e., with water droplet 113b, θ₅ can be about 80°). Thus, a thin hydrophilic film, such as a silicon nitride thin film, may detach relatively easily from a hydrophobic substrate, such as substrate C 113 subject to a hard baking process at a temperature of about 150° C. for about 30 minutes.

FIG. 17 also illustrates that, relative to a surface characteristic-altering property induced by a selected surface treatment to substrate ‘D’ 114 as illustrated with respect to FIGS. 14A and 14B, a hard baking process at a temperature of about 120° C. for about 60 minutes may not effect a sufficient change in substrate hydrophobicity, as evidenced by the difference between contact angle θ₆ formed on the surface of substrate ‘D’ 114 prior to the hard baking process (i.e., with water droplet 114a, θ₆ can be about 70°); and contact angle θ₇ formed on the surface of substrate ‘D’ 114 subsequent to the hard bake process (i.e., with water droplet 114b, θ₇ can be about 85°). Thus, a thin hydrophilic film, such as a silicon nitride thin film, may detach relatively easily from a hydrophobic substrate, such as substrate ‘D’ 114 subject to a hard baking process at a temperature of about 120° C. for about 60 minutes.

FIG. 17 also illustrates that, relative to a surface characteristic-altering property induced by a selected surface treatment to substrate ‘E’ 115 as illustrated with respect to FIGS. 15A and 15B, a plasma treatment of oxygen plasma generated by 1,200 W electric power for about 30 seconds may effect a change in substrate hydrophobicity as to become hydrophilic, as evidenced by the difference between contact angle θ₈ formed on the surface of substrate ‘E’ 115 prior to the oxygen plasma treatment process (i.e., with water droplet 115a, θ₈ can be about 70°); and contact angle θ₉ formed on the surface of substrate ‘E’ 115 subsequent to the plasma treatment process (i.e., with water droplet 115b, θ₉ can be about 5°). Thus, a thin hydrophilic film, such as a silicon nitride thin film, may not detach relatively easily from a hydrophobic substrate having a hydrophilic body formed thereon, such as substrate E 115 subject to a plasma treatment of oxygen plasma generated by 1,200 W electric power for about 30 seconds.

FIG. 17 also illustrates that, relative to a surface characteristic-altering property induced by a selected surface treatment to substrate ‘F’ 116 as illustrated with respect to FIGS. 16A and 16B, a plasma treatment of oxygen plasma generated by 1,200 W electric power for about 50 seconds may effect a change in substrate hydrophobicity as to become hydrophilic, as evidenced by the difference between contact angle θ₁₀ formed on the surface of substrate ‘F’ 116 prior to the oxygen plasma treatment process (i.e., with water droplet 116a, θ₁₀ can be about 70°); and contact angle θ₁₁ formed on the surface of substrate ‘F’ 116 subsequent to the plasma treatment process (i.e., with water droplet 116b, θ₁₁ can be about 10°). Thus, a thin hydrophilic film, such as a silicon nitride thin film, may not detach relatively easily from a hydrophobic substrate having a hydrophilic body formed thereon, such as substrate ‘F’ 116 subject to a plasma treatment of oxygen plasma generated by 1,200 W electric power for about 50 seconds.

Display Apparatus

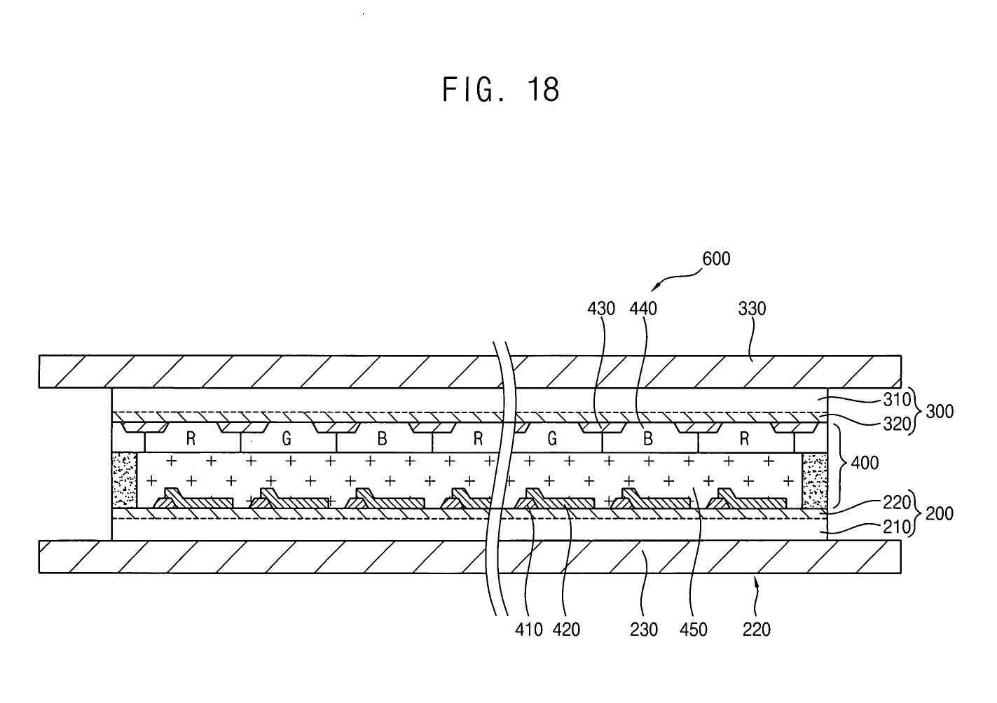

In FIG. 18, display apparatus 600 can include first substrate 200, second substrate 300, and display element 400. First substrate 200 can includes first hydrophobic body 210 and first hydrophilic body 220. An exemplary first hydrophobic body 210 can be formed from, without limitation, synthetic resins. A contact angle of a water droplet dropped onto the first hydrophobic body 210 may be substantially no less than 40°. First hydrophilic body 220 may be formed by treating first hydrophobic body 210 with a plasma treatment process. A contact angle of a water droplet dropped onto first hydrophilic body 220 can be in a range of about 2° to about 40°. In selected embodiments, first hydrophobic body 210 and first hydrophilic body 220 can be integrally formed. Alternatively, first hydrophilic body 220 may be disposed on first hydrophobic body 210.

Although first substrate 200 may exhibit a first degree of hardness, it may yet be flexible, can be flexible, it, and it may be desirable to form first sub-body 230 to impart support to first substrate 200, where such support may be beneficial for forming thereon display element 400. First sub-body 230 can have a second degree of hardness, which may be higher than the first degree of hardness of the first substrate 200. For example, a glass substrate may be employed as the first sub-body 230.

The second substrate 300 can includes second hydrophobic body 310 and a second hydrophilic body 320. Exemplary second hydrophobic body 310 can be formed from, without limitation, synthetic resins. A contact angle of a water droplet dropped onto the second hydrophobic body 310 can be substantially no less than about 40°. Second hydrophilic body 320 may be formed by treating second hydrophobic body 310 with a plasma treatment process. A contact angle of a water droplet dropped onto the second hydrophilic body 320 can be in a range of between about 2° to about 40°. In selected embodiments, second hydrophobic body 310 and second hydrophilic body 320 can be integrally formed with each other. Alternatively, second hydrophilic body 320 may be disposed on second hydrophobic body 310.

Although second substrate 300 may exhibit a first degree of hardness yet be flexible, and it may be desirable to form first sub-body 230 to impart support to first substrate 300, where such support may be beneficial for forming thereon display element 400. The second sub-body 330 can have a second degree of hardness, which can be higher than the first degree of hardness of the second substrate 300. For example, a glass substrate may be employed as the second sub-body 330.

Display element 400 can includes thin film transistor 410, pixel electrode 420, black matrix 430, color filter 440, and liquid crystal layer 450. Thin film transistor 410 and the pixel electrode 420 can be formed on first substrate 200, and black matrix 430 and 440 can be formed on second substrate 300. Also, the liquid crystal layer 450 can be disposed between first substrate 200 and second substrates 300.

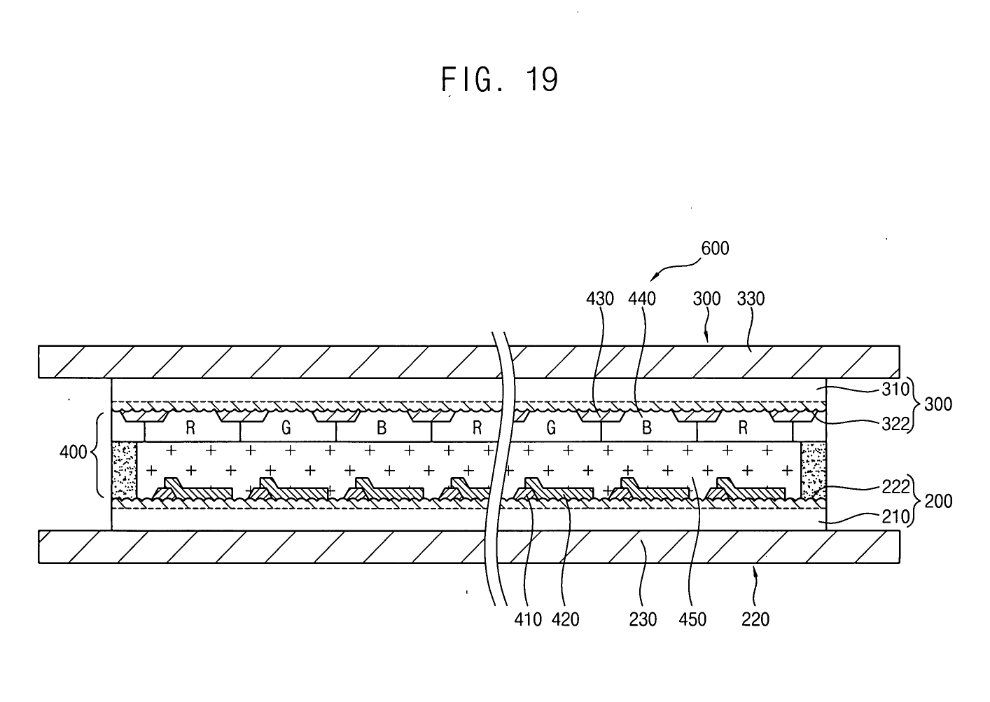

FIG. 19 is a cross-sectional view illustrating a display apparatus according to another exemplary embodiment herein, similar to the display apparatus in FIG. 18, with modifications to one or both of for the first and second substrates. Thus, the same reference numerals will be used to refer to the same or like parts as those described in FIG. 18. In FIG. 19, first embossing patterns 222 can be formed on a surface of first hydrophilic body portion 220 of first substrate 200. First embossing patterns 222 can increase a contact area between the hydrophilic body portion 220 and a thin film transistor 410 formed on the first hydrophilic body portion 220 so that the adhesive force between the first hydrophilic body portion 220 and the thin film transistor 410 formed on the first hydrophilic body portion 220 may be enhanced. First embossing patterns 222 also can increase a contact area between first hydrophilic body portion 220 and hydrophilic thin film pixel electrode 420, so that the adhesive force between the first hydrophilic body portion 220 and hydrophilic thin film pixel electrode 420 may be enhanced.

Additionally, second embossing patterns 322 can be formed on a surface of second hydrophilic body portion 320 of second substrate 300. Second embossing patterns 322 can increase a contact area between second hydrophilic body portion 320 and black matrix 430 formed on second hydrophilic body portion 320, so that the adhesive force between the second hydrophilic body portion 320 and black matrix 430 formed on the second hydrophilic body portion 320 may be enhanced. Second embossing patterns 322 also can increase a contact area between second hydrophilic body portion 320 and hydrophilic thin film color filter 440 formed on second hydrophilic body portion 320, so that the adhesive force between second hydrophilic body portion 320 and hydrophilic thin film color filter 440 may be enhanced.

It may be desirable to formhydrophilic display elements for displaying an image on a flexible substrate so that the display elements are tightly attached to the flexible substrate.

Having described the example embodiments of the present invention and its advantages, it is noted that various changes, substitutions and alterations can be made herein without departing from the spirit and scope of the invention as defined by appended claims.

What is claimed is:

1. A substrate for a display apparatus, comprising:
a hydrophobic body
a hydrophilic body portion formed on the hydrophobic body; and
a hydrophilic thin film formed on the hydrophilic body portion, wherein the hydrophilic thin film forms a display element.

2. The substrate of claim 1, wherein the hydrophobic body and the hydrophilic body portion are integrally formed.

3. The substrate of claim 1, wherein the hydrophilic body portion comprises embossing patterns formed on a surface of the hydrophilic body portion.

4. The substrate of claim 1, wherein the hydrophobic body comprises at least two hydrophobic thin films.

5. The substrate of claim 4, wherein the hydrophilic body portion is formed on a hydrophobic thin film that makes contact with the hydrophilic thin film.

6. The substrate of claim 1, wherein the hydrophobic body is flexible.

7. The substrate of claim 1, wherein the hydrophobic body has a first degree of hardness and further comprising a sub-body having a second degree of hardness, wherein the second degree of hardness is greater than the first degree of hardness and wherein the sub-body supports the hydrophobic body.

8. The substrate of claim 1, wherein the hydrophobic body comprises one of polycarbonate, polyimide, polyethersulphone, polyacrylate, polyethylenenaphthelate and polyethyleneterephehalate.

9. The substrate of claim 1, wherein a contact angle of a water droplet dropped onto the hydrophilic body portion with respect to a surface of the hydrophilic body portion is in a range of between about 2 degrees to about 40 degrees.

10. The substrate of claim 1, wherein the hydrophobic body comprises:
a signal line formed on the hydrophilic body portion;
a thin film transistor electrically connected to the signal line; and
a pixel electrode electrically connected to the thin film transistor.

11. A method of manufacturing a substrate for a display apparatus, comprising:
disposing a bare hydrophobic substrate in a plasma chamber; and
forming a hydrophilic body portion on a surface of the bare hydrophobic substrate by exposing the bare hydrophobic substrate to a plasma generated in the plasma chamber.

12. The method of claim 11, wherein the plasma is generated from a source gas comprising one of oxygen (O₂), argon (Ar), tetrafluoromethane (CF₄), trifluoromethane (CHF₃), hydrogen chloride (HCl), and a mixture thereof.

13. The method of claim 11, wherein the bare hydrophobic substrate is exposed to the plasma for between about 1 second to about 300 seconds.

14. The method of claim 11, wherein a contact angle of a water droplet dropped onto the hydrophilic body portion with respect to a surface of the hydrophilic body portion is in a range of about 2 degrees to about 40 degrees.

15. The method of claim 11, further comprising forming a hydrophilic thin film on the hydrophilic body portion.

16. The method of claim 15, further comprising forming a silicon nitride hydrophilic thin film.

17. A display apparatus comprising:
a first substrate having a first hydrophobic body and a first hydrophilic body portion formed on the first hydrophobic body;
a second substrate having a second hydrophobic body and a second hydrophilic body portion formed on the second hydrophobic body; and
a display element disposed between the first substrate and the second substrate and including a hydrophilic thin film, wherein the display element is for displaying an image.

18. The display apparatus of claim 17, wherein at least one of the first hydrophilic body portion and the second hydrophilic body portion comprises a embossing patterns formed on a surface of at least one of the first hydrophilic body portions and the second hydrophilic body portion.

19. The display apparatus of claim 17, further comprising a liquid crystal layer disposed between the first substrate and the second substrate.

20. The display apparatus of claim 17, wherein the first hydrophobic body and the first hydrophilic body portion are integrally formed, and wherein the second hydrophobic body and the second hydrophilic body portion are integrally formed.

21. The display apparatus of claim 17, wherein at least one of the first hydrophobic body and second hydrophobic body comprises at least two hydrophobic thin films.

22. The display apparatus of claim 17, wherein at least one of the first substrate and the second substrates is flexible.

23. The display apparatus of claim 17, wherein at least one of the first hydrophobic body and the second hydrophobic body exhibit a first degree of hardness, wherein at least one of the first substrate and the second substrate further comprises a respective first sub-body and second sub-body, wherein at least one of the first sub-body and the second sub-body exhibit a second degree of hardness, and wherein the second degree of hardness is greater that the first degree of hardness, and wherein the first and second hydrophobic bodies are respectively supported thereby.
